(19) United States
(12) Patent Application Publication
(10) Pub. No.: US 2024/0286200 A1
(43) Pub. Date: Aug. 29, 2024

(54) COATED TOOL

(71) Applicant: KYOCERA CORPORATION, Kyoto-shi, Kyoto (JP)

(72) Inventors: Hiroyuki KINJO, Satsumasendai·shi, Kagoshima (JP); Hayato KUBO, Satsumasendai-shi, Kagoshima (JP); Tadashi KATSUMA, Satsumasendai·shi, Kagoshima (JP)

(21) Appl. No.: 18/574,043

(22) PCT Filed: Jan. 25, 2022
(86) PCT No.: PCT/JP2022/002520

§ 371 Date: Dec. 25, 2023

(30) Foreign Application Priority Data
Jul. 2, 2021 (JP) 2021-110444

(51) Int. Cl. B23B 27/14

(52) U.S. Cl. CPC B23B 27/148; B23B 2224/32; B23B 2228/105

(57) ABSTRACT

A coated tool in a non-limiting embodiment of the present disclosure includes a base composed of cemented carbide, and a coating layer located on a surface of the base. The coating layer includes a first layer in contact with the base. The first layer contains Ti(C_{X}N_{1-X}) (0≤x≤1). The base includes a plurality of WC particles. A region from the surface of the base to a depth of 5 μm is a first region. A region from the surface of the base to a depth of 100-200 μm is a second region. A maximum value of a carbon content in the first region is a first carbon content, and a maximum value of a carbon content in the second region is a second carbon content. The first carbon content is higher than the second carbon content. An average value of KAM values in the first region is less than 0.4°.

### CROSS-REFERENCE TO RELATED APPLICATION

The present application claims priority to Japanese Patent Application No. 2021-110444, filed Jul. 2, 2021. The contents of this application are incorporated herein by reference in their entirety.

### TECHNICAL FIELD

The present disclosure relates to a coated tool including a coating layer on a surface of a base.

### BACKGROUND

Coated tools have conventionally been known in which one or a plurality of titanium carbide layers, titanium nitride layers, titanium carbonitride layers, aluminum oxide layers, and aluminum titanium nitride layers are formed on a surface of a base composed of cemented carbide.

There has been a demand for enhancing wear resistance and fracture resistance in the coated tools. For example, a cutting tool is increasingly used in heavy interrupted machining or the like in which a cutting edge is subjected to a large impact along with higher efficiency of a machining process. Under these severe machining conditions, it is required to avoid peeling and chipping of the coating layer due to the large impact exerted on the coating layer.

Japanese Unexamined Patent Publication No. 2011-152602 (Patent Document 1) discloses a cutting tool in which a titanium nitride layer is physically deposited as a coating layer onto a surface of a base. This publication also discloses that a crystal orientation of titanium nitride crystal grains in a surface of the coating layer obtained by measurement with Electron Backscatter Diffraction (EBSD) apparatus is controlled to fall within a predetermined range.

The coated tools are required to be usable under more severe machining conditions in order to increase machining efficiency. It is required to avoid the peeling and chipping of the coating layer by enhancing adhesion between the base composed of cemented carbide and the coating layer.

### SUMMARY

A coated tool in a non-limiting embodiment of the present disclosure includes a base composed of cemented carbide, and a coating layer located on a surface of the base. The coating layer includes a first layer in contact with the base. The first layer includes Ti(C_{X}N_{1-X}) (0≤x≤1). The base includes a plurality of WC particles. A region from the surface of the base to a depth of 5 μm is a first region, and a region from the surface of the base to a depth of 100-200 μm is a second region. A maximum value of a carbon content in the first region is a first carbon content, and a maximum value of a carbon content in the second region is a second carbon content. Under conditions that a distance between adjacent pixels (step size) is 0.1 μm and a misorientation between the adjacent pixels of 5° or more is regarded as a grain boundary, a value obtained by measuring the WC particles with electron backscatter diffraction (EBSD) method using a scanning electron microscope with a backscattered electron diffraction image system is a KAM value. The first carbon content is higher than the second carbon content. An average value of KAM values in the first region is less than 0.4°.

### BRIEF DESCRIPTION OF THE DRAWINGS

FIG. 1 is a perspective view illustrating a coated tool (cutting tool) in a non-limiting embodiment of the present disclosure; and

FIG. 2 is a sectional view of the coated tool illustrated in FIG. 1.

### EMBODIMENT

### <Coated Tools>

A coated tool 1 (hereinafter also referred to as “tool 1”) in a non-limiting embodiment of the present disclosure is described in detail below with reference to the drawings. For the convenience of description, the drawings referred to in the following illustrate, in simplified form, only main members necessary for describing embodiments. The tool 1 may therefore include any arbitrary structural member not illustrated in the drawings referred to. Dimensions of the members in each of the drawings faithfully represent neither dimensions of actual structural members nor dimensional ratios of these members.

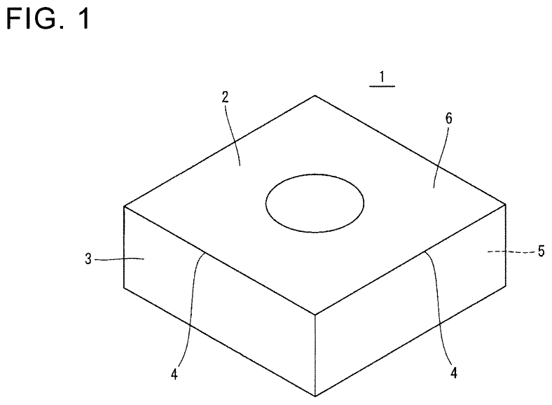

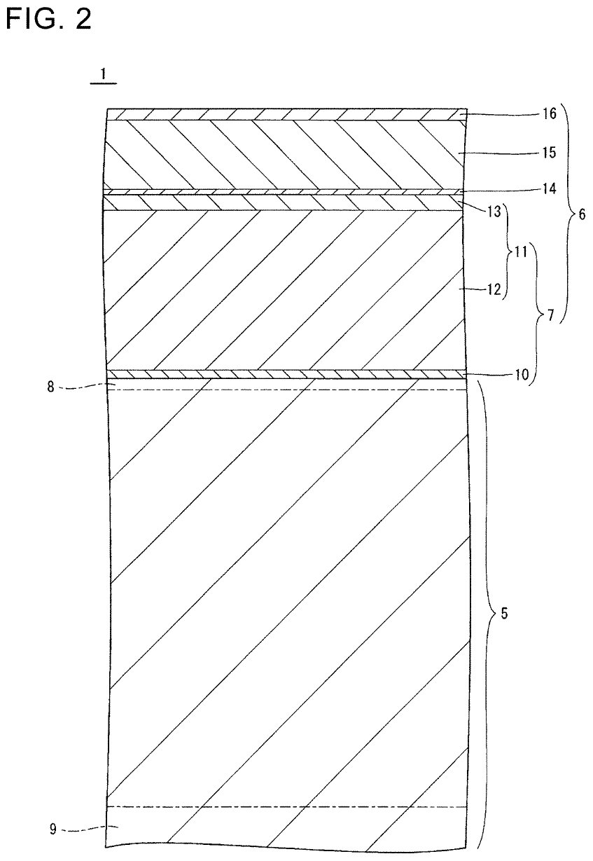

FIGS. 1 and 2 illustrate a cutting tool (a cutting insert) as an embodiment of the tool 1. The tool 1 is not limited to the cutting tool. The tool 1 may be, for example, a digging tool and a blade.

The tool 1 may include a first surface 2 (an upper surface in FIG. 1), a second surface 3 (a lateral surface in FIG. 1), and a cutting edge 4 located on an intersection of the first surface 2 and the second surface 3 as in a non-limiting embodiment illustrated in FIG. 1. At least a part of the first surface 2 is servable as a rake surface. At least a part of the second surface 3 is servable as a flank surface. The cutting edge 4 is usable for machining a workpiece. In other words, the tool 1 is capable of carrying out a machining process by bringing the cutting edge 4 into contact with the workpiece. The cutting edge 4 may be located on the whole or a part of the intersection of the first surface 2 and the second surface 3.

The tool 1 may include a base 5 and a coating layer 6 located on a surface of the base 5 as in the embodiment illustrated in FIG. 2.

The base 5 may be composed of cemented carbide. Examples of composition of the cemented carbide may include WC—Co, WC—TiC—Co and WC—TiC—TaC—Co, in which WC (tungsten carbide), TiC (titanium carbide) and TaC (tantalum carbide) are hard particles, and Co (cobalt) is a binding phase. The above compositions are examples, and the configuration of the base 5 may be, for example, other configurations including a hard phase composed of WC particles and at least one kind of selected from the group consisting of carbides, nitrides, and carbonitrides of group 4, group 5 and group 6 metals in the periodic table, and a binding phase composed of Co.

The coating layer 6 may include a first layer 7 in contact with the base 5. The first layer 7 may contain Ti(C_{X}N_{1-X}) (0≤x≤1).

The base 5 may include a plurality of WC particles. A region from the surface of the base 5 to a depth of 5 μm is a first region 8, and a region from the surface of the base 5 to a depth of 100-200 μm is a second region 9. A maximum value of carbon content in the first region 8 is a first carbon content, and a maximum value of carbon content in the second region 9 is a second carbon content. If a distance between adjacent pixels (step size) is 0.1 μm, a misorientation between the adjacent pixels is 5° or more, it is regarded as a grain boundary. Under these conditions, a value obtained by measuring the WC particles with electron backscatter diffraction (EBSD) method using a scanning electron microscope (SEM) with a backscattered electron diffraction image system is a KAM value. The first carbon content may be higher than the second carbon content. An average value of KAM values in the first region 8 may be less than 0.4°.

In the above case, deformation of the WC particles that are present in the surface of the base 5 decreases, and residual stress between the base 5 and the first layer 7 decreases. Consequently, the adhesion between the base 5 and the coating layer 6 can be enhanced to avoid the peeling and chipping of the coating layer 6. If the average value of the KAM values in the first region 8 is less than 0.3°, the adhesion between the base 5 and the coating layer 6 can be further enhanced.

KAM (Kernel Average Misorientation) represents a local misorientation that is a difference in crystal orientation between adjacent measurement points measured with EBSD method, and the KAM value is a value having correlation with dimensions, such as plastic strain. KAM also reflects local deformation and dislocation density in nanoscale. Therefore, local plastic deformation in nanoscale is confirmable by measuring the KAM value. The average value of KAM values is obtainable by measuring KAM values at individual positions in an observation region, and by averaging the KAM values.

Strain might occur between a base composed of cemented carbide and a coating layer in contact with the base in the conventional step of depositing the coating layer. This may be caused by the fact carbon decreases in a region in the vicinity of the surface of the base as compared to the interior of the base, resulting in alteration of the surface of the base in the step of depositing the coating layer. Due to the alteration of the surface of the base, micro plastic strain is likely to remain at a part of the WC particles that are present in the surface of the base. Consequently, the coating layer might be likely to peel off from the base if the tool 1 is subjected to large impact.

Strain between the base 5 and the coating layer 6 is reduced in the tool 1 by increasing a content ratio of carbon in the region in the vicinity of the surface of the base 5 relative to the interior of the base 5. This achieves that the average value of the KAM values in the region in the vicinity of the surface of the base 5 is less than 0.4°. Thus, because the tool 1 is configured to avoid the micro plastic strain occurred in the WC particles that are present in the vicinity of the surface of the base 5, the strain between the base 5 and the coating layer 6 is small. Accordingly, the coating layer 6 is less likely to peel off from the base 5 even if the tool 1 is subjected to large impact.

A lower limit value of the average value of the KAM values in the first region 8 may be 0.1° or more. The base 5 may have a thickness of 1 mm or more. A mean particle diameter of the WC particles may be 0.01-20.0 μm. The mean particle diameter of the WC particles may be measured by image analysis. In this case, an equivalent circle diameter may be the mean particle diameter of the WC particles. The mean particle diameter of the WC particles may be measured by the following procedure. Firstly, an SEM image may be obtained by observing a cross section of the base 5 with an SEM at 3000-5000× magnification. At least 50 pieces or more of WC particles on the SEM image may be specified and extracted. Thereafter, the mean particle diameter of the WC particles may be obtained by calculating the equivalent circle diameter with image analysis software “ImageJ (1.52).”

The first carbon content may be 1.10 times or more the second carbon content. In other words, a ratio of the first carbon content to the second carbon content (the first carbon content/the second carbon content) may be 1.10 or more. This further improves the adhesion between the base 5 and the coating layer 6. An upper limit value of the above ratio may be less than 1.40. If the ratio of the first carbon content (the first carbon content/the second carbon content) is 1.40 or more, the adhesion between the base 5 and the first layer 7 might degrade, and the coating layer 6 might be likely to peel off from the base 5. The carbon content is measurable by Auger Electron Spectroscopy (AES analysis). The first carbon content and the second carbon content are not limited to a specific value. For example, the first carbon content may be set to 20-75 atom %, and the second carbon content may be set to 15-70 atom %.

A carbon content in a central part in a thickness direction of the first layer 7 is a third carbon content. The third carbon content may be higher than the second carbon content. Specifically, a ratio of the third carbon content to the second carbon content (the third carbon content/the second carbon content) may be 1.70 or more. This further improves the adhesion between the base 5 and the coating layer 6. The above ratio may be 1.50 or more. An upper limit value of the above ratio may be 2.50 or less. The third carbon content is not limited to a specific value. For example, the third carbon content may be set to 15-75 atom %.

The first layer 7 may have a thickness of 1 μm or more. In this case, an orientation of crystal particles in a region ranging from the surface of the base 5 to 0.3 μm in the first layer 7 may be different from an orientation of crystal particles in the central part in the thickness direction of the first layer 7. This leads to high fracture resistance. The orientation of the crystal particles is measurable by EBSD method.

The first layer 7 is not limited to having a specific thickness. For example, the thickness of the first layer 7 may be set to 6-15 μm. In cases where the first layer 7 has a thickness of 6 μm or more, particularly, 10 μm or more, high wear resistance is attainable. In cases where the first layer 7 has a thickness of 15 μm or less, particularly, 13 μm or less, high fracture resistance is attainable.

The first layer 7 containing Ti(C_{X}N_{1-X}) (0≤x≤1) may be configured by a single layer, or may be a configuration where a plurality of layers (layered parts) are laminated one upon another. For example, the first layer 7 may include a first part 10 having a layer shape in contact with the base 5, and a second part 11 having a layer shape located on the first part 10 as in the embodiment illustrated in FIG. 2.

The carbon contained in the first part 10 may be less than the carbon contained in the second part 11. Specifically, a main component of the first part 10 may be titanium nitride (TiN). A main component of the second part 11 may be titanium carbonitride Ti(C_{X}N_{1-X}) (0<x<1). If the first layer 7 has the above configuration, it is possible to further enhance the adhesion between the base 5 and the first layer 7. In particular, in cases where the first part 10 of the first layer 7 is composed of TiN, components of the cemented carbide are less likely to diffuse from the base 5 to the coating layer 6, thereby avoiding alteration of the surface of the base 5. The term “main component” as used herein denotes the component having the largest value of mass % compared with other components.

The first part 10 may be constituted by titanium nitride particles whose mean particle diameter is 0.05-0.5 μm. The titanium nitride particles may be columnar crystals extending in a vertical direction with respect to the surface of the base 5.

The tool 1 may include a portion where epitaxial growth takes place between the WC particles located in the surface of the base 5 and the titanium nitride particles located on a side of the base 5 in the first part 10. Additionally, Co may be diffused at a ratio of 0.2-3 mass % in the first part 10. The diffusion of Co in this manner leads to further enhanced adhesion between the base 5 and the coating layer 6.

The second part 11 may be configured by a third part 12 having a layer shape whose main component is so-called MT (Moderate Temperature)-titanium carbonitride, and a fourth part 13 that is located on the third part 12 and has a layer shape whose main component is HT (High Temperature)-titanium carbonitride.

The third part 12 may contain acetonitrile (CH₃CN) gas as a raw material, and may be composed of columnar crystals deposited at a deposition temperature that is a relatively low temperature of 780-900° C. In this case, a width of the columnar crystal in a direction parallel to the surface of the base 5 may be 0.4 μm or less. The columnar crystals having the above configuration lead to further enhanced adhesion between the first part 10 and the fourth part 13.

The fourth part 13 may be composed of granular crystals deposited at a deposition temperature that is relatively high temperature of 900-1100° C. A projection tapering upward and having a triangular shape in cross-sectional view may be formed on a surface of the fourth part 13. The fourth part 13 having the projection leads to enhanced adhesion to a second layer 14 described later, thereby avoiding the peeling and chipping of the coating layer 6.

The first part 10 and the second part 11 are not limited to having a specific thickness. For example, the thickness of the first part 10 may be set to 0.5-3 μm. The thickness of the second part 11 may be set to 5.5-14.5 μm. In cases where the first part 10 has a thickness of 0.5-3 μm, particularly, 0.5-2.0 μm, and the second part 11 has a thickness of 5.5-14.5 μm, particularly, 8.0-12.5 μm, the coating layer 6 has enhanced adhesion to the base 5, and has enhanced wear resistance.

The coating layer 6 may further include a second layer 14 and a third layer 15 in addition to the first layer 7. The second layer 14 may be located on the first layer 7 (the fourth part 13). The third layer 15 may be located on the second layer 14.

The second layer 14 may contain titanium and oxygen, and may be composed of, for example, TiCO, TiNO, TiCNO, TiAlCO, and TiAICNO. Specifically, the second layer 14 may contain Ti(C_{X}N_{1-x-y}O_{y}) (0<x<1, 0<y<1). The third layer 15 may contain aluminum oxide.

If the coating layer 6 includes the third layer 15, it is possible to further enhance the wear resistance of the coating layer 6. If the second layer 14 is located between the first layer 7 and the third layer 15, it is possible to enhance the adhesion between the first layer 7 and the third layer 15.

If the second layer 14 contains the above component, aluminum oxide particles constituting the third layer 15 become α-type crystal structure. The third layer 15 composed of the aluminum oxide having the α-type crystal structure has high hardness. This contributes to enhancing the wear resistance of the coating layer 6.

If x+y=1 in cases where the second layer 14 contains Ti(C_{X}N_{1-x-y}O_{y}), the Ti(C_{X}N_{1-x-y}O_{y}) in the second layer 14 has a needle shape and becomes a crystal structure extending at a height of 0.05-0.5 μm toward a vertical direction with respect to the surface of the base 5. This structure leads to enhanced adhesion between the second part 11 and the third layer 15.

If the third layer 15 is composed of aluminum oxide having the α-type crystal structure, hardness of the third layer 15 can be enhanced, and the wear resistance of the coating layer 6 can be improved. If I(116) and I(104) are the first and second strongest among peaks detected by X-ray diffraction measurement from a side of the surface of the third layer 15, there is a tendency that the coating layer 6 is less prone to wear.

The second layer 14 and the third layer 15 are not limited to having a specific thickness. For example, the thickness of the second layer 14 may be set to 0.05-5.0 μm. The thickness of the third layer 15 m may be set to 1.0-15 μm.

The coating layer 6 may further include a fourth layer 16 in addition to the first layer 7, the second layer 14, and the third layer 15. The fourth layer 16 may be located on the third layer 15. The fourth layer 16 may contain Ti(C_{X}N_{1-x-y}O_{y}) (0≤x≤1, 0≤y<1). The fourth layer 16 may be composed of other material, such as chromium nitride. The fourth layer 16 is not limited to having a specific thickness. For example, the thickness of the fourth layer 16 may be set to 0.1-3 μm.

The coating layer 6 may have a structure where the first part 10 composed of a titanium nitride layer, the second part 11 composed of a titanium carbonitride layer, the second layer 14, the third layer 15, and the fourth layer 16 are laminated in this order from a side of the base 5.

A thickness of the individual layers and a form of crystals constituting the individual layers are measurable by observing an electron micrograph photograph (an SEM photograph or a Transmission Electron Microscope (TEM) photograph) in a cross section of the tool 1. The fact that the form of the crystals constituting the individual layers in the coating layer 6 is a columnar shape means a state where a ratio of an average crystal width to a length of individual crystals in a thickness direction of the coating layer 6 is 0.3 or less on average. Crystals whose ratio of the average crystal width to the length of the individual crystals in the thickness direction of the coating layer 6 exceeds 0.3 on average are defined that the form of the crystals is a granular shape.

### <Method for Manufacturing Coated Tool>

A method for manufacturing a coated tool in a non-limiting embodiment of the present disclosure is described below by exemplifying the case of manufacturing the tool 1.

Firstly, a mixed powder is obtained by suitably adding and mixing metal powder, carbon powder or the like to an inorganic powder of metal carbide, nitride, carbonitride, oxide or the like, with which it is possible to form cemented carbide that becomes a base 5 by sintering. Then, a molded body is obtained by molding the mixed powder into a predetermined tool shape with a known molding method, such as press molding, casting molding, extrusion molding or cold isostatic pressing.

Subsequently, the base 5 composed of the cemented carbide is obtained by sintering the obtained molded body in a vacuum or a non-oxidizing atmosphere. A surface of the base 5 may be subjected to polishing process and honing process.

Subsequently, the tool 1 is obtained by depositing a coating layer 6 on the surface of the obtained base 5 by Chemical Vapor Deposition (CVD) method.

Firstly, a mixed gas composed of 2-10 vol % of titanium tetrachloride (TiCl₄) gas and the rest, namely, hydrogen (H₂) gas may be prepared and introduced into a chamber (furnace) to carry out a pretreatment at a deposition temperature (furnace temperature) of 800-940° C. and a pressure of 8-50 kPa for 1-10 minutes. In this case, a carbon content ratio in a region in the vicinity of the surface of the base 5 tends to be high. This avoids that when subsequently depositing the first layer 7, carbon components diffuse and move toward the first layer 7 in the vicinity of the surface of the base 5, thereby avoiding that significant strain occurs in the WC particles in the vicinity of the surface of the base 5. Accordingly, if the base 5 is subjected to the pretreatment, the first carbon content tends to be higher than the second carbon content, and an average value of KAM values in the first region 8 tends to be less than 0.4°.

Subsequently, a first part 10 composed mainly of titanium nitride (TiN) in the first layer 7 is deposited. For example, deposition conditions of the first part 10 may be as follows. A mixed gas composed of 0.5-10 vol % of titanium tetrachloride (TiCl₄) gas, 10-60 vol % of nitrogen (N₂) gas, and the rest, namely, hydrogen (H₂) gas is prepared as a reaction gas composition. The mixed gas is introduced into the chamber. A deposition temperature is 800-940° C., and a pressure is 8-50 kPa. Under these deposition conditions, a deposition start temperature may be set to a temperature lower than a deposition termination temperature by 10-50° C., and the temperature may be raised during the deposition. In this case, it is possible to avoid significant strain in the WC particles in the vicinity of the surface of the base 5 by avoiding diffusion of W and Co elements in the vicinity of the surface of the base 5.

Next, a second part 11 in the first layer 7 is deposited. Firstly, a third part 12 composed mainly of MT-titanium carbonitride in the second part 11 is deposited. For example, deposition conditions of the third part 12 may be as follows. A mixed gas composed of 0.5-10 vol % of titanium tetrachloride (TiCl₄) gas, 0.1-3.0 vol % of acetonitrile (CH₃CN) gas, and the rest, namely, hydrogen (H₂) gas is prepared as a reaction gas composition. The mixed gas is introduced into the chamber. A deposition temperature is 780-900° C., and a pressure is 5-25 kPa. Under these deposition conditions, a content ratio of the acetonitrile (CH₃CN) gas may be increased at a later-stage deposition than an early-stage deposition. In this case, it is possible to configure so that an average crystal width of columnar crystals of titanium carbonitride constituting the third part 12 can have a larger value on a side of the surface than on a side of the base 5.

Subsequently, a fourth part 13 composed mainly of HT-titanium carbonitride in the second part 11 is deposited. For example, deposition conditions of the fourth part 13 may be as follows. A mixed gas composed of 1-10 vol % of titanium tetrachloride (TiCl₄) gas, 5-30 vol % of nitrogen (N₂) gas, 0.1-10 vol % of methane (CH₄) gas, and the rest, namely, hydrogen (H₂) gas is prepared as a reaction gas composition. The mixed gas is introduced into the chamber. A deposition temperature is 900-1100° C., and a pressure is 5-40 kPa.

Subsequently, a second layer 14 is deposited. For example, deposition conditions of the second layer 14 may be as follows. A mixed gas composed of 3-15 vol % of titanium tetrachloride (TiCl₄) gas, 3-10 vol % of methane (CH₄) gas, 0.5-2.0 vol % of carbon monoxide (CO) gas, and the rest, namely, hydrogen (H₂) gas is prepared as a reaction gas composition. The mixed gas is introduced into the chamber, a deposition temperature is 900-1050° C., and a pressure is 5-40 kPa. As a reaction gas composition, 10-25 vol % of nitrogen (N₂) gas may be added to the above. Argon (Ar) gas may be used instead of the nitrogen (N₂) gas. Under the above deposition conditions, needle crystals extending in a vertical direction with respect to the surface of the base 5 are generated in the second layer 14, thereby enhancing adhesion to a third layer 15 to be deposited next.

Subsequently, the third layer 15 is deposited. For example, deposition conditions of the third layer 15 may be as follows. A mixed gas composed of 0.5-5.0 vol % of aluminum trichloride (AlCl₃) gas, 0.5-5.0 vol % of hydrogen chloride (HCl) gas, 0.5-5.0 vol % of carbon dioxide (CO₂) gas, 0-1.0 vol % of hydrogen sulfide (H₂S) gas, and the rest, namely, hydrogen (H₂) gas is used as a reaction gas composition. A deposition temperature is changed to 950-1100° C., and a pressure is changed to 5-20 kPa. Under the above deposition conditions, a growth state of aluminum oxide crystals is adjusted to control aluminum oxide crystal orientation. The deposition conditions of the third layer 15 is not limited to a single deposition process. The third layer 15 may be deposited in a deposition process made up of a plurality of stages.

Thereafter, a fourth layer 16 is deposited. The following is an example of deposition conditions in cases where the fourth layer 16 is composed of TiN. A mixed gas composed of 0.1-10 vol % of titanium tetrachloride (TiCl₄) gas, 10-60 vol % nitrogen (N₂) gas, and the rest, namely, hydrogen (H₂) gas is prepared as a reaction gas composition. The mixed gas is introduced into the chamber. A deposition temperature is 960-1100° C., and a pressure is 10-85 kPa.

A part where the cutting edge 4 is located on the surface of the coating layer 6 in the tool 1 thus obtained may be subjected to a polishing process. Consequently, the cutting edge 4 can be made smooth, and welding of a workpiece can be avoided, thus leading to the tool 1 having more excellent fracture resistance.

Although the present disclosure is described in detail below by exemplifying examples, the present disclosure is not limited to the following examples.

### EXAMPLES

### [Samples Nos. 1 to 4]

### <Coated Tool Manufacturing>

Firstly, a base was manufactured. Specifically, 6 mass % of metal cobalt powder having a mean particle diameter of 1.2 μm, 0.5 mass % of titanium carbide powder having a mean particle diameter of 2.0 μm, 5 mass % of niobium carbide powder having a mean particle diameter of 2.0 μm, and the rest, namely, tungsten carbide powder having a mean particle diameter of 1.5 μm were added and mixed together in their respective proportions. A molded body was obtained by molding a mixture thus obtained into a cutting tool shape (CNMG120408) by press molding. The obtained molded body was then subjected to a debinding process, and was sintered in a vacuum or in a non-oxidizing atmosphere, thereby manufacturing the base composed of cemented carbide. Thereafter, the manufactured base was subjected to a brushing process, and a part of the base serving as a cutting edge was subjected to round honing. A mean particle diameter of WC particles included in the base was measured by the above-mentioned image analysis, and the result was 1.0 μm.

Subsequently, a coating layer was deposited on the obtained base by CVD method. A reaction gas having a composition presented in Table 1 was used for deposition. The coating layer was deposited under deposition conditions presented in Table 2. Individual compounds were indicated by chemical symbol in Tables 1 and 2. A numerical value in parentheses in Table 2 is a thickness of individual layers. The thickness of the coating layer presented in Table 2 is a value obtained by cross-section measurement using an SEM. Samples Nos. 1 to 4 are different in pretreatment time. Sample No. 1 has zero pretreatment time. That is, Sample No. 1 is not subjected to the pretreatment.

### <Evaluations>

### (Average Value Determination of KAM Values in First Region)

Determination of KAM in the first region in each of the obtained coated tools was made by EBSD method as follows. A cross section of the coated tool was subjected to buffing using colloidal silica. Then, EBSD (model number JSM7000F) manufactured by Oxford Co., Ltd. was used to divide a measurement region into rectangular regions (pixels). A pixel orientation in each of divided regions was measured by obtaining a Kikuchi pattern obtained from backscattered electrons of electron beam made incident on a surface of each of Samples. With analysis software of the same system, orientation data thus measured was analyzed to calculate various parameters.

Observation conditions were as follows. An acceleration voltage was 15 kV, a measurement area was a width 50 μm×depth 2 μm on the surface of the cemented carbide that was the base, and a distance between adjacent pixels (step size) was 0.1 μm. If a misorientation between the adjacent pixels was 5° or more, it was regarded as a crystal boundary. Regarding KAM, an average value of misorientations between pixels that were present in a crystal grain and adjacent pixels that were present in a range not exceeding the crystal boundary was calculated, and an average value of KAM values was determined as an average value of all pixels constituting an entire measurement area. In the measurement of the average value of the KAM values, arbitrary three eye sights in the first region were measured, and an average value thereof was evaluated. The results were presented in Table 3.

### (First to Third Carbon Contents Measurements)

The first to third carbon contents were measured by AES analysis, and a ratio (the first carbon content/the second carbon content) and a ratio (the third carbon content/the second carbon content) were calculated. AES analysis conditions were as follows, and results were presented in Table 3.
Apparatus: “Model 680” manufactured by PHI
Acceleration voltage: 10 kV
Specimen current: 10 nA
Electron probe diameter: 0.1 μm or less

### (Machining Test)

Using the obtained coated tools, an intermittent machining test was conducted to evaluate fracture resistance. The intermittent machining conditions were as follows, and results were presented in Table 3.

Workpiece: Rolled steel for general structure, steel with eight flutes (SS400)
Tool shape: CNMG120408
Cutting speed: 300 m/min
Feed rate: 0.30 mm/rev
Depth of Cut: 1.0 mm
Others: Using a water-soluble cutting fluid
Evaluation item: Measuring the number of impacts until occurrence of a fracture.

TABLE 1

| | | | | | | | | | | | Furnace | |
|---|---|---|---|---|---|---|---|---|---|---|---|---|
| Coating | Reaction gas composition (vol %) | | | | | | | | | | temperature | Pressure |
| layer | TiCl₄ | N₂ | CH₃CN | CH₄ | CO | AlCl₃ | HCl | CO₂ | H₂S | H₂ | (° C.) | (kPa) |
| Pretreatment | 6.0 | — | — | — | — | — | — | — | — | Rest | 850 | 16 |
| TiN-1 | 1.0 | 55.0 | — | — | — | — | — | — | — | Rest | 850 | 16 |
| TiCN-1(MT) | 7.0 | — | 0.5 | — | — | — | — | — | — | Rest | 850 | 10 |
| TiCN-2(HT) | 5.5 | 24.0 | — | 8.5 | — | — | — | — | — | Rest | 950 | 10 |
| TiCO | 7.0 | — | — | 5.5 | 0.5 | — | — | — | — | Rest | 950 | 15 |
| Al₂O₃ | — | — | — | — | — | 4.2 | 0.9 | 4.5 | 0.3 | Rest | 950 | 9 |
| TiN-2 | 3.0 | 40.0 | — | — | — | — | — | — | — | Rest | 1010 | 30 |

TABLE 2

| | Pre- | Coating layer | | | | | |
|---|---|---|---|---|---|---|---|
| | treat- | First layer | | | | | |
| Sam- | ment | | Second part | | Sec- | | |
| ple | time | First | Third | Fourth | ond | Third | Fourth |
| No. | (min.) | part | part | part | layer | layer | layer |
| 1 | 0 | TiN-1 | TiCN- 1 | TiCN-2 | TiCO | Al₂O₃ | TiN-2 |
| 2 | 2 | (2 μm) | (8 μm) | (0.3 μm) | (0.1 | (6 μm) | (1 μm) |
| 3 | 5 | | | | μm) | | |
| 4 | 7 | | | | | | |

| | | | | | Average | | | |
|---|---|---|---|---|---|---|---|---|
| | | | | | value of | | | |
| | | First | Second | Third | KAM | | | Machining test |
| | | carbon | carbon | carbon | values | First carbon | Third carbon | Number of |
| Sample | Pretreatment | content | content | content | in first region | content/Second | content/Second | impacts |
| No. | time (min.) | (atom %) | (atom %) | (atom %) | (°) | carbon content | carbon content | (times) |
| 1 | 0 | 39 | 40 | 62 | 0.4 | 0.98 | 1.55 | 55000 |
| 2 | 2 | 42 | 39 | 65 | 0.3 | 1.08 | 1.67 | 65000 |
| 3 | 5 | 46 | 37 | 68 | 0.2 | 1.24 | 1.84 | 80000 |
| 4 | 7 | 48 | 35 | 68 | 0.2 | 1.37 | 1.94 | 68000 |

As shown in Table 3, Samples Nos. 2 to 4 subjected to the pretreatment had longer lifetime than Sample No. 1. Measurement results showed that the first carbon contents of Samples Nos. 2 to 4 were higher than the second carbon contents, and the average value of the KAM values in the first region was less than 0.4°.

### DESCRIPTION OF THE REFERENCE NUMERAL

1 coated tool (cutting tool)
2 first surface
3 second surface
4 cutting edge
5 base
6 coating layer
7 first layer
8 first region
9 second region
10 first part
11 second part
12 third part
13 fourth part
14 second layer
15 third layer
16 fourth layer

1. A coated tool, comprising:
a base containing a plurality of WC particles; and
a coating layer located on the base, wherein
the coating layer comprises a first layer in contact with the base,
the first layer containing Ti(C_{X}N_{1-X})(0≤x≤1),
a region from a surface of the base to a depth of 5 μm is a first region,
a region from the surface of the base to a depth of 100-200 μm is a second region,
a carbon content ratio in the first region is a first carbon content,
a carbon content ratio in the second region is a second carbon content,
under conditions that a distance between adjacent pixels (step size) is 0.1 μm and a misorientation between adjacent pixels of 5° or more is regarded as a grain boundary, a value obtained by measuring the WC particles with electron backscatter diffraction (EBSD) method using a scanning electron microscope with a backscattered electron diffraction image system is a KAM value,
the first carbon content is higher than the second carbon content, and
an average value of KAM values in the first region is less than 0.4°.

2. The coated tool according to claim 1, wherein the first carbon content is 1.10 times or more than the second carbon content.

3. The coated tool according to claim 1, wherein the average value of the KAM values is less than 0.3°.

4. The coated tool according to claim 1, wherein
a carbon content ratio in a central part in a thickness direction of the first layer is a third carbon content, and
the third carbon content is higher than the second carbon content.

5. The coated tool according to claim 1, wherein
the first layer has a thickness of 1 μm or more, and
an orientation of crystal particles in a region ranging from the surface of the base to 0.3 μm in the first layer is different from an orientation of crystal particles in a central part in a thickness direction of the first layer.

6. The coated tool according to claim 1, wherein the first carbon content is less than 1.40 times the second carbon content.

7. The coated tool according to claim 1, wherein the first carbon content is from 20 mol % to 75 mol %.

8. The coated tool according to claim 1, wherein the second carbon content is from 15 mol % to 70 mol %.
